(19) United States
(12) Patent Application Publication
(10) Pub. No.: US 2012/0146078 A1
(43) Pub. Date: Jun. 14, 2012

(54) High Efficiency Conversion LED

(76) Inventors: Frank Baumann, Regensburg (DE); Norbert Boenisch, Munchen (DE); Tim Fiedler, Munchen (DE); Frank Jermann, Konigsbrunn (DE); Stefan Lange, Augsburg (DE); Reiner Windisch, Pettendorf (DE)

(21) Appl. No.: 13/391,180

(22) PCT Filed: Aug. 11, 2010
(86) PCT No.: PCT/EP10/61674

§ 371 Date: Feb. 17, 2012

(30) Foreign Application Priority Data
Aug. 17, 2009 (DE) 10 2009 037 732.8

(51) Int. Cl. H01L 33/50

(52) U.S. Cl. 257/98; 257/E33.061

(57) ABSTRACT

A conversion LED with a chip which emits primary blue radiation, and a layer containing luminescent substance upstream of the chip which converts at least part of the primary radiation of the chip into secondary radiation, wherein a first garnet A3B5O12:Ce yellow-green emitting luminescent substance and a second nitride silicate M2X5Y8:D orange-red emitting luminescent substance is used, wherein the peak wavelength of the primary radiation is in the range of 430 to 450 nm, in particular of up to 445 nm, while the first luminescent substance is a garnet with the cation A=Lu or a mixture of Lu, Y with up a Y fraction of up to 30%, and wherein B has fractions of both Al and Ga, while the second luminescent substance is a nitride silicate which contains both Ba and Sr as cation M, and in which the doping consists of Eu, wherein the second luminescent substance contains 35 to 75 mol.-% Ba for the component M, remainder is Sr, where X=Si and Y=N.

### TECHNICAL FIELD

The invention is based on a conversion LED according to the preamble of claim 1. Such conversion LEDs are in particular suitable for general lighting.

### PRIOR ART

A conversion LED is known from U.S. Pat. No. 6,649,946, which to obtain a white LED uses a blue chip together with Sr2Si5N8:Eu, wherein YAG:Ce is also used as an additional luminescent substance to improve color reproduction. However, only a few efficient LEDs can be realized in this way.

A conversion LED is known from U.S. Pat. No. 7,297,293 which to obtain a white LED uses a blue chip together with (Sr,Ca)2Si5N8:Eu, wherein YAG:Ce and similar luminescent substances with partial replacement of Y by Gd or partial replacement of Al by Ga is also used as an additional luminescent substance to improve color reproduction. However, only a few efficient LEDs can be realized in this way.

A conversion LED is known from EP-A 1 669 429 which uses a blue chip together with special (Sr,Ba)2Si5N8:Eu luminescent substance to obtain a white LED, wherein Lu-AG:Ce as well as similar luminescent substances which are co-doped with Ce and Pr are also used as additional luminescent substances to improve color reproduction.

### SUMMARY OF THE INVENTION

The object of this invention is to provide a high efficiency conversion LED, wherein the conversion LED in particular achieves a high useful life.

This object is achieved by the characterizing features of claim 1.

Particularly advantageous embodiments are to be found in the dependent claims.

According to the inventive a high efficiency conversion LED is now provided. Not all luminescent substances are stable in LEDs operated at high currents, here in particular at least 250 mA, preferably at least 300 mA, known as high performance LEDs. In particular this problem applies to nitride or oxinitride luminescent substances such as nitride silicate M2Si5N8:Eu. Many such luminescent substances, in particular M2Si5N8:D nitride with D as an activator, suffer significant conversion losses during operation in an LED. In a stress test with up to 700 mA continuous current, white LEDs with such luminescent substances over a short period of time (typically 1000 hours) lose up to 50% of their conversion efficiency. This results in marked instability of the color location.

White LEDs are constantly gaining in significance in general lighting. In particular, the demand for warm white LEDs with low color temperatures, preferably in the 2900 to 3500 K range, in particular 2900 to 3100 K, and for good color reproduction, in particular Ra is at least 93, preferably 96, and at the same time for high efficiency. As a rule these targets are achieved by combining a blue LED with yellow and red luminescent substances. The spectra of all these solutions have a region in the blue-green spectral range in which little radiation is emitted (blue-green gap), resulting in poor color reproduction. To compensate very long-wave blue LEDs are usually used (approx. 460 nm). On the part of chip technology, however, it is advantageous to use LEDs of shorter chip wavelengths as these are significantly more efficient. Wavelengths (peak) of between 430 to 455 nm, in particular 435 to 445 nm are desirable.

If the blue-green portion of the overall range is essentially determined solely by the blue LED, as is the case with previous combinations of long-wave blue LED and yellow as well as red luminescent substances, this results in the overall CRI of the white LED being heavily dependent on the chip wavelength used. For technical reasons, however, a relatively broad range of chip wavelengths must be used in practice, resulting in major fluctuations in the CRI. Furthermore, the luminescent substances must be highly stable with regard to chemical influences, for example, oxygen, humidity, interactions with encapsulation materials, as well as to radiation. In order to ensure a stable color location as the system temperature rises, in addition luminescent substances with very slight temperature slaking characteristics are required.

The most efficient warm white solutions to date are based on a combination of a yellow garnet luminescent substance such as YAG:Ce or YAGaG:Ce, which contains both Al and Ga, and a nitride silicate such as (Ba,Sr,Ca)₂Si₅N₈:Eu. In order to achieve sufficiently good color reproduction, the use of very long-wave blue LEDs (approx. 455 to 465 nm) is necessary here, system efficiency being significantly restricted as a result, however. If shorter chip wavelengths of 430 to 450 nm, preferably up to 445 nm, are used with the previous luminescent substances, however, color reproduction is poor, in particular in the blue-green spectral range. Furthermore, the heavy dependence of the CRI on the blue wavelength results in significant fluctuations of the CRI within the product. The stability of the previous solution in the LED is barely sufficient. In the case of high currents, here in particular at least 250 mA, preferably at least 300 mA, particularly preferably at least 350 mA, it is critical as the thermal load continues to rise.

The new solution consists of a combination of a green to green-yellow emitting garnet luminescent substance and a short-wave, narrow band orange-red emitting nitride silicate luminescent substance. Compared with the previously used yellow (YAG) or green-yellow (YAGaG) garnet, the green garnet luminescent substance has a strongly green-shifted emission, at the same time optimum excitation is strongly short wave-shifted. This green shift of the garnet results in a significant reduction of the blue-green gap in the white spectrum.

Due to these properties significantly shorter wave LEDs (approx. 435 nm to 445 nm peak wavelength instead of 455 nm in the previous solution) can be used and at the same time a CRI of the white LED greater than 80 can be achieved. As a result of the special spectral properties of the newly developed luminescent substance mixture, in addition the CRI remains roughly constant over a broad range of blue LED wavelengths, thus ensuring even color quality within an “LED bin”. In addition the newly developed combination of these luminescent substances is distinguished by very high chemical and photochemical stability as well as very slight temperature slaking characteristics.

Decisive progress now consists of a simultaneous improvement of several properties key from the perspective of application having been achieved, namely with regard to aging stability, efficiency, usable chip wavelength range and temperature stability of the luminescent substances. The difference between this new solution and the already known warm white solutions with low color temperatures, preferably in the range 2900 to 3500 K, in particular 2900 to 3100 K is:
Very strong green-shifted garnet luminescent substance. This has advantages for: CRI, visual assessment, temperature stability, λ_{dom} should preferably be between 552-559 nm, FWHM should preferably be between 105-113 nm (relative to excitation at 435 nm).
Very short chip wavelength of 430 to 450 nm peak wavelength. This is a major advantage with regard to high efficiency;
Short-wave emitting and narrow-band red luminescent substance; λ_{dom} should preferably be between 596-604 nm, the FWHM should preferably be smaller than 100 nm, particularly preferably smaller than 90 nm (relative to excitation at 435 nm). This has advantages for: service life of the LED, visual assessment.

Essential features of the invention in the form of a numbered list are:
1. Conversion LED with a chip which emits primary radiation, as well as a luminescent substance-containing layer upstream from the chip, which converts at least part of the primary radiation of the chip into secondary radiation, wherein a first garnet A3B5O12:Ce yellow-green emitting luminescent substance and a second nitride silicate M2X5Y8:D orange-red emitting luminescent substance is used, characterized in that the peak wavelength of the primary radiation is in the range 430 to 450 nm, in particular up to 445 nm, while the first luminescent substance is a garnet with the cation A=Lu or a mixture of Lu, Y with up a Y fraction of up to 30%, and wherein B has fractions of both Al and Ga, while the second luminescent substance is a nitride silicate which contains both Ba and Sr as cation M, and in which the doping consists of Eu, wherein the second luminescent substance contains 35 to 75 mol.-% Ba for the component M, the remainder is Sr, wherein X=Si and Y=N.
2. Conversion LED as claimed in claim 1, characterized in that in component B the first luminescent substance contains 10%, preferably 15%, up to 40 mol.-% Ga, preferably up to 35%, in particular 20 to 30%, the remainder is Al.
3. Conversion LED as claimed in claim 1, characterized in that the first luminescent substance contains 1.5% to 2.9 mol.-% Ce, in particular 1.8 to 2.6 mol.-% Ce, in component A, remainder is A, in particular only Lu or Lu with a fraction Y of up to 25%.
4. Conversion LED as claimed in claim 1, characterized in that the second luminescent substance contains 35 to 65 mol.-% Ba, in particular 40 to 60%, in the component M, remainder is Sr, where X=Si and Y=N.
5. Conversion LED as claimed in claim 1, characterized in that the second luminescent substance contains 1 to 20 mol.-% Eu, in particular 2 to 6%, in the component M, remainder is (Ba, Sr).
6. Conversion LED as claimed in claim 1, characterized in that the second luminescent substance is (Sr0.48Ba0.48Eu0.04)2Si5N8.
7. Conversion LED as claimed in claim 6, characterized in that the first luminescent substance is A3B5O12, with A=75 to 100% Lu, remainder Y and a Ce-content of 1.5 to 2.5%, with B=10 to 40% Ga, remainder Al.
8. Conversion LED as claimed in claim 7, characterized in that the first luminescent substance is A3B5O12, with A=80 to 100% Lu, remainder Y and a Ce-content of 1.5 to 2.5%, with B=15 to 30% Ga, remainder Al.
9. Conversion LED as claimed in claim 8, characterized in that the first luminescent substance is (Lu0.978Ce0.022)3A13.75Gal.25012.

### BRIEF DESCRIPTION OF THE DRAWINGS

Hereinafter the invention is explained in detail on the basis of several exemplary embodiments. The figures show:

FIG. 1 a conversion LED;

FIG. 2 a comparison of the temperature dependence of various green emitting luminescent substances;

FIG. 3 a comparison of the temperature dependence of various red emitting luminescent substances;

FIG. 4 a comparison of the efficiency loss of nitride silicates for various Eu doping contents as a function of the Ba fraction;

FIG. 5 a comparison of the efficiency loss of nitride silicates in various load scenarios as a function of the Ba fraction;

FIG. 6 a comparison of the converter loss before and after loading for various luminescent substances;

FIG. 7 a comparison of the time function of the converter losses for various luminescent substances;

FIG. 8 a comparison of the CRI for various luminescent substance mixtures with primary excitation wavelength shifting;

FIG. 9 a comparison of the overall emission of a conversion LED with various primary emissions;

FIG. 10-12 a comparison of the emission of LuAGaG or YAGaG or mixed Sion with various peak positions of primary emission (Ex);

FIG. 13 an LED module with remotely attached luminescent substance mixture;

FIG. 14 a comparison of emission for Lu garnets with various Y contents.

### PREFERRED EMBODIMENT OF THE INVENTION

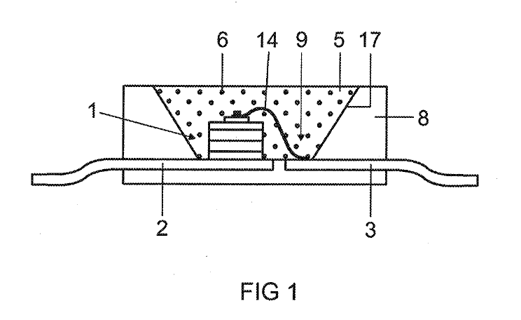

FIG. 1 shows the structure of a conversion LED for white light based on RGB as known per se. The light source is a semiconductor device with a high-current InGaN blue-emitting chip and an operating current of 350 mA. It has a peak emission wavelength of 430 to 450 nm peak wavelength, for example, 435 nm, and is embedded in an opaque basic housing 8 in the region of a recess 9. The chip 1 is connected to a first connection 3 and directly to a second electrical contact 2 via a bonding wire 14. The recess 9 is filled with a filling compound 5, the main components of which are silicon (70 to 95 weight percent) and luminescent substance pigments 6 (less than 30 weight percent). A first luminescent substance is a green-emitting LuAGaG:Ce, a second luminescent substance is a red-emitting nitride silicate SrBaSi5N8:Eu. The recess has a wall 17 which serves as a reflector for primary and secondary radiation from the chip 1 or the pigments 6.

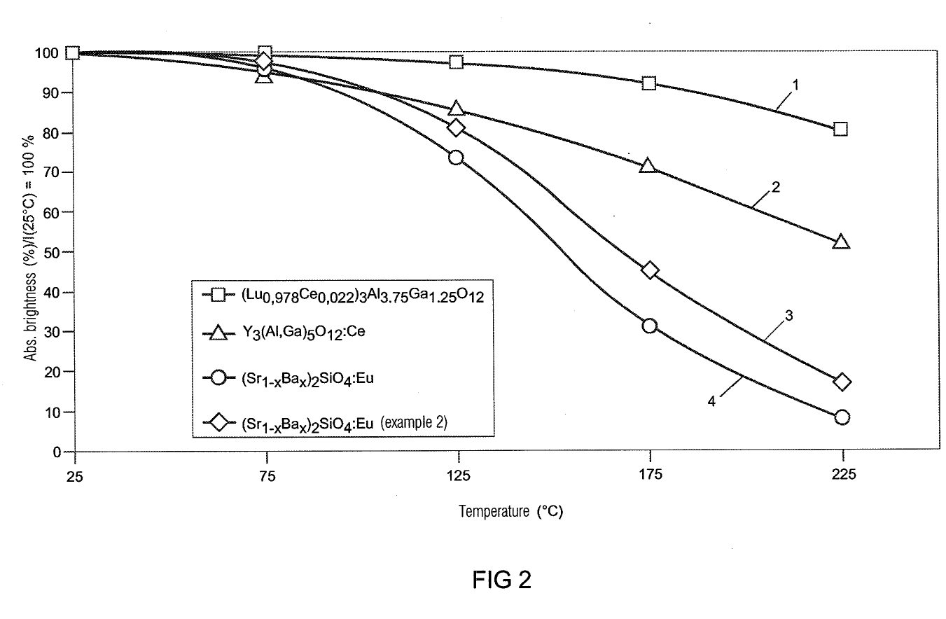

FIG. 2 shows the temperature slaking characteristics of various yellow-green-emitting luminescent substances which can in principle be easily started using the chip in FIG. 1. The luminescent substance A3B5O12:Ce, where A=mainly Lu, in the embodiment with the preferred composition LuA-GaG, that is to say Lu3 (Al, Ga) 5012: Ce with approx. fraction of 25% Ga for 5 B components (preferably 10-40% Ga fraction, particularly preferably 15-30% Ga fraction) and approx. 2.2% Ce (preferably 1.5-2.9% Ce, particularly preferably 1.8-2.6% Ce, each in relation to the fraction A), is characterized by very slight temperature slaking. A preferred luminescent substance is (Lu0.978Ce0.022)3A13.75Gal.25O12, see curve 1. The graph shows a comparison with other yellow and green luminescent substances with considerably poorer temperature slaking characteristics. Orthosilicates (curve 3, 4) are wholly unsuitable, but GaG (curve 2) is unusable.

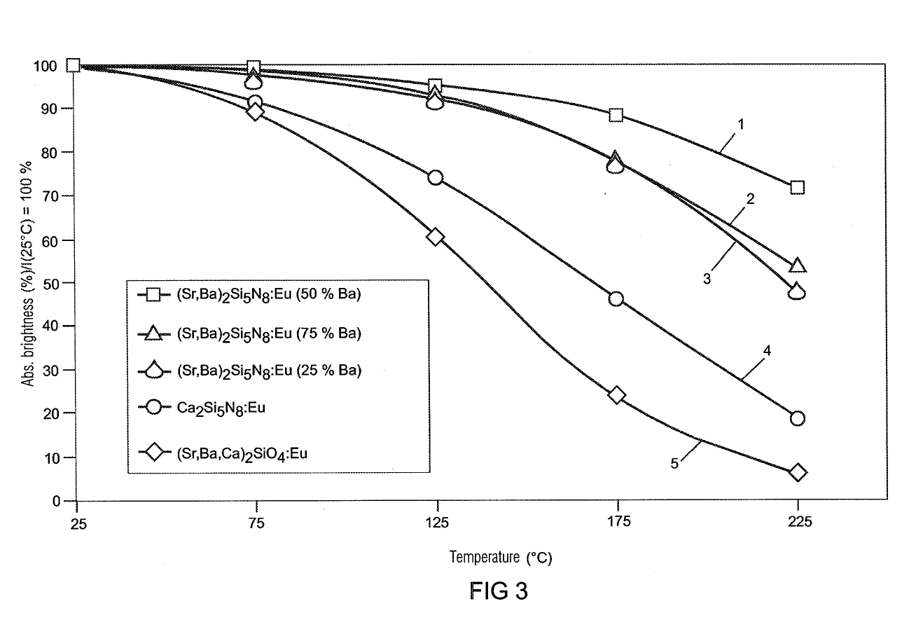

FIG. 3 shows the temperature slaking characteristics of various orange-red-emitting luminescent substances which can in principle be easily started using the chip in FIG. 1. The new luminescent substance of the type nitride silicate M2Si5N8:Eu with the preferred composition (Sr,Ba)2Si5N8:Eu with approx. 50% Ba ((x=0.5); in general x=0.35-0.75 is preferred, x=0.4-0.6 is particularly preferred) and approx. 4% Eu ((y=0.04); generally an Eu fraction of M of x=0.01-0.20 is preferred, x=0.02-0.06 is particularly preferred), is characterized by very slight temperature slaking. A nitride silicate with x=0.4-0.6 of type Sri-ₓ-_{y}/2Baₓ−y/2Eu_{y}) 2SisN₈, see curve 1 is suitable. The graph shows a comparison with other orange/red luminescent substances. Nitride silicates with x=0.25 or x=0.75 are significantly less suitable, see curve 2 and 3. Ca-nitride silicates (curve 4) and orthosilicates (curve 5) are unsuitable.

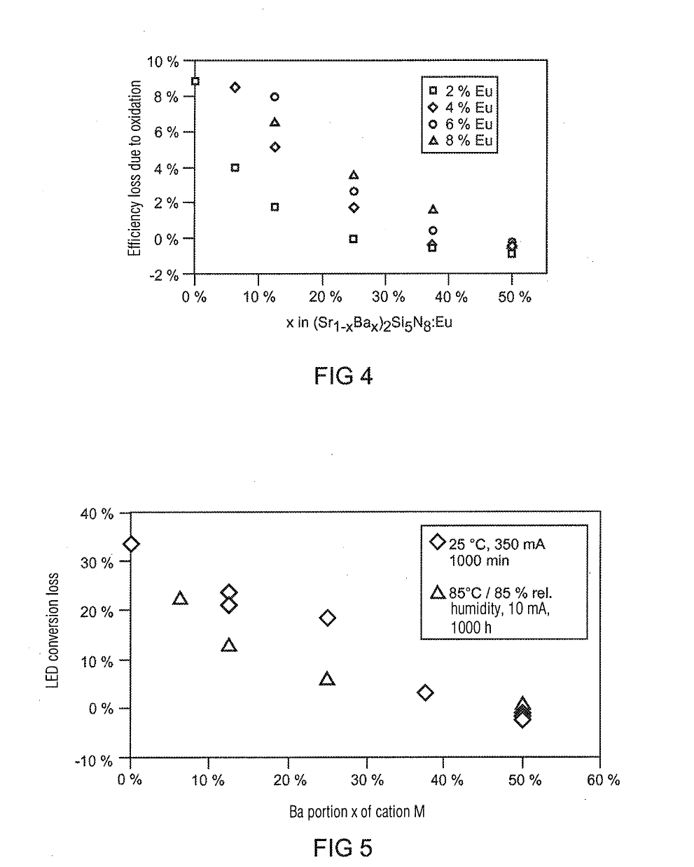

FIG. 4 shows the result of an oxidation stability test in which the stability of the system (Sr,Ba)2Si5N8:Eu is ascertained with variable Ba-content. To do this the sample was first characterized, then baked in air at 150° C. for 68 h and then characterized again. The difference of both efficiencies at different times produces the efficiency loss. The best luminescent substances are perfectly stable in the context of measurement errors. The luminescent substance with approx. 45 to 53% Ba is preferred with approx. 4% Eu fraction of M, in particular the luminescent substance (Sr0.48Ba048Eu0.04)2Si5N8.

FIG. 5 shows the result of an LED ageing test in which the stability of the system Sr,Ba)2Si5N8:Eu was ascertained with variable Ba content x. A blue high-power LED (Xₚₑₐₖ at approx. 435 nm) was poured into silicon with a dispersion of the respective luminescent substance and operated at 350 mA for 1000 min. The relative intensities of the blue LED peak of the primary emission and the luminescent substance offpeak were measured at the start and at the end of the test and the loss of conversion efficiency relative to the intensity of the blue LED peak determined therefrom. FIG. 5 (square measuring points) shows a clear increase in stability with increasing barium content. The luminescent substance proving itself to be optimum with approx. 50% Ba and approx. 4% Eu ((Sr0.48Ba0.48Eu0.04)2Si5N8, L358) is perfectly stable within the context of the measurement errors. In a further test (1000 h, 10 mA, 85% rel. humidity, 85° C.) the same trend is revealed (triangular measuring points).

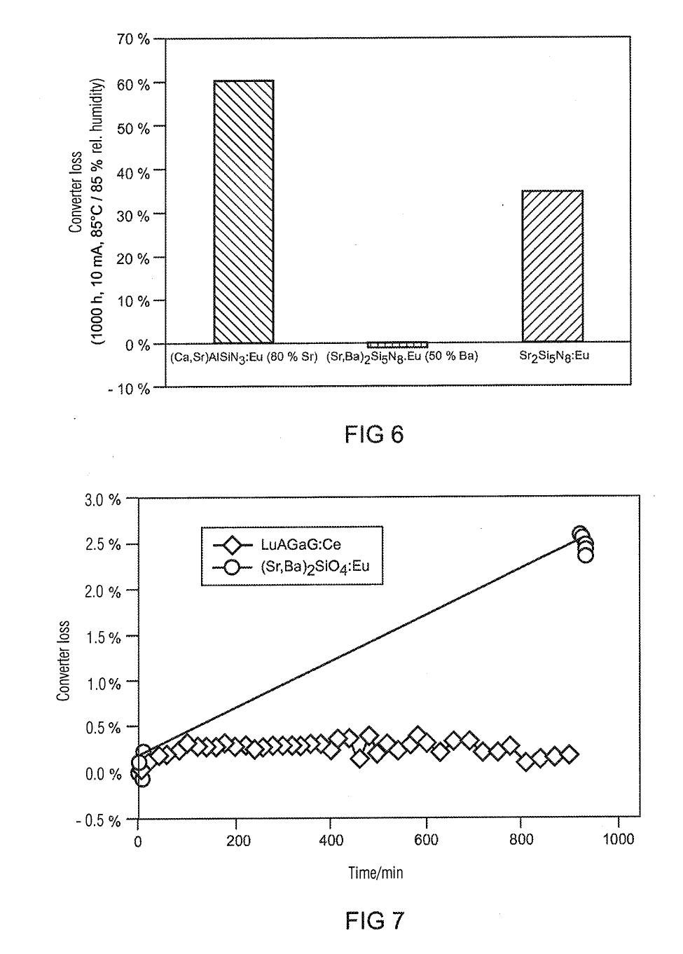

FIG. 6 shows the comparison of three red luminescent substance systems with narrow-band emission with λ_{dom}<605 nm in an LED ageing test (1000 h, 10 mA, 85% rel. humidity, 85° C.) the first column relates to a Cal-sin with Sr fraction, the second column is the best luminescent substance according to the invention, a mixed nitride silicate with equal fractions of Sr and Ba, the third column shows the behavior of pure Sr nitride silicate. The mixed nitride silicate is perfectly stable within the context of measurement errors, while the systems for comparison age very strongly.

FIG. 7 shows the stability of the yellow-green component. In an LED ageing test the stability of the new green luminescent substance with the preferred composition (Lu-AGaG with approx. 25% Ga and approx. 2.2% Ce, (Lu0.978Ce0.022)3A13.75Gal.25O12) was ascertained and compared with other known yellow/green luminescent substances. In the process a blue high-power LED (λₚₑₐₖ=435 nm) with dispersion of the respective luminescent substance was poured into silicon and this was operated at 350 mA for 1000 h. The relative intensity of the blue LED peak and the luminescent substance peak were measured at the start and at the end the loss of conversion efficiency determined therefrom.

The new LuAGaG luminescent substance is perfectly stable within the context of measurement errors (square measuring points) while an orthosilicate reveals clear symptoms of ageing under comparable conditions (round measuring points).

The color reproduction of the warm white LED with the new yellow-green with orange-red luminescent substance mixture according to the inventive is practically independent from the LED wavelength used. A shift in the blue wavelength of 9 nm only results in a CRI loss of 1 point. The counter-example of the previous mixture already loses 5 points where there is a difference of 7 nm in blue wavelength (see Table 1). In order to reduce the CRI loss to 1 point, the addition of a third luminescent substance is necessary, which influences efficiency and color steering negatively.

TABLE 1

| | Peak | | | | | | |
|---|---|---|---|---|---|---|---|
| | wavelength | | Luminescent | | Luminescent | | |
| | of the | Color | substance 1 | Luminescent | substance 3 | | |
| | blue LED/ | tempera- | (green- | substance 2 | (blue- | Ratio | |
| Sample | ni | ture/K | yellow) | (orange-red) | green) | yellow:red | CRI Ra8 |
| 1 | 444 | 3000 | LuAGaG: 2.2%Ce | (Sr,Ba)2Si5N8: Eu | | 9.3:1 | 83 |
| | | | (25%Ga) | (50% Ba) | | | |
| 2 | 435 | 3050 | LuAGaG: 2.2%Ce | (Sr,Ba)2Si5N8: Eu | | 8.9:1 | 82 |
| | | | (25%Ga) | (50% Ba) | | | |
| VGL1 | 462 | 3200 | YAG: 3%Ce | (Sr,Ca)2Si5N8: Eu | | 9:1 | 81 |
| | | | | (60% Sr) | | | |
| VGL2 | 455 | 3250 | YAG: 3%Ce | (Sr,Ca)2Si5N8: Eu | | 10.3:1 | 76 |
| | | | | (60% Sr) | | | |
| VGL3 | 455 | 3200 | YAG: 3%Ce | (Sr,Ca)2Si5N8: Eu | greenchloro- | 9:1 | 80 |
| | | | | (60% Sr) | silicate | | |
| VGL4 | 462 | 3250 | YAGaG: 4%Ce | (Sr,Ca)2Si5N8: Eu | | 6.1:1 | 86 |
| | | | (25%Ga) | (60% Sr) | | | |
| VGL5 | 455 | 3250 | YAGaG: 4%Ce | (Sr,Ca)2Si5N8: Eu | | 7:1 | 83 |
| | | | (25%Ga) | (60% Sr) | | | |
| VGL6 | 444 | 3200 | YAGaG: 4%Ce | (Sr,Ca)2Si5N8: Eu | — | 7:1 | 77 |
| | | | (25%Ga) | (60% Sr) | | | |

in the table CRI = color reproduction index

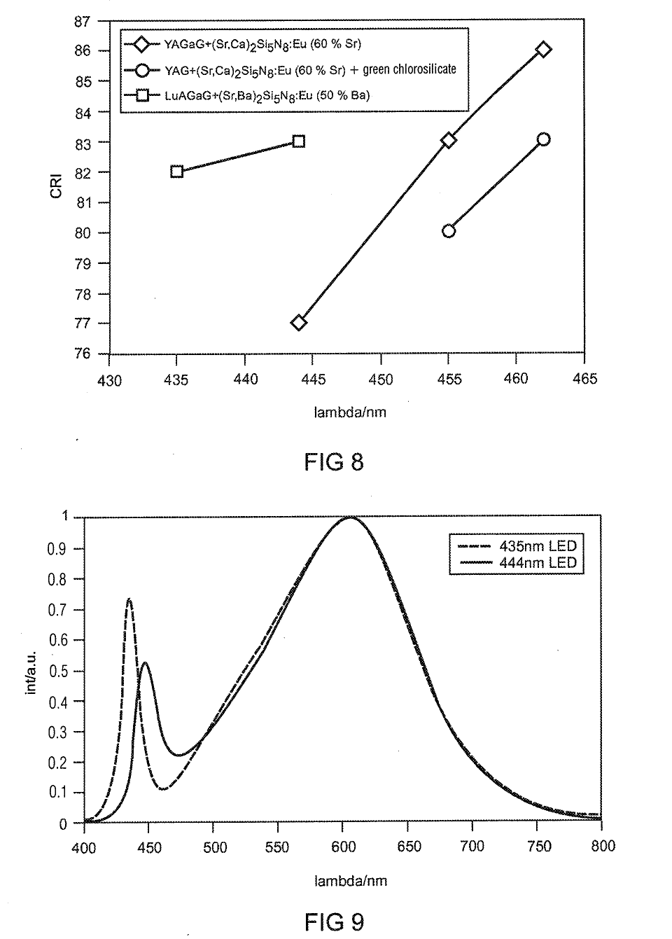

FIG. 8 shows the color reproduction index (CRI) Ra8 for various systems. The color reproduction of a warm white LED with the new luminescent substance mixture (sample 1 and 2) according to the inventive is practically independent of the LED wavelength used. A shift in the blue wavelength of 9 nm only results in a CRI loss of 1 point (square measuring points). The comparative example of the previous mixture already loses 5 points if there is a difference of 7 nm in blue wavelength (round measuring points; see table, VGL 1 and VGL 3). In order to reduce CRI loss to 1 point, the addition of a third luminescent substance is necessary (VGL2), which influences efficiency and color steering negatively. An additional comparative example (diamond-shaped measuring points) relates to YAG as a yellow-green component with Sr—Ba nitride silicate. Astonishingly, this system is far worse than the related system according to the inventive and as poor as the three-luminescent substance version (VGL2).

FIG. 9 explains the reason for the (almost perfect) independence of the color reproduction index CRI from the blue wavelength: The luminescent substance emission shifts surprisingly in the system according to the inventive with increasingly shortwave excitation wavelength significantly to short wavelengths. This produces a certain compensation in the overall spectrum: The missing blue-green fractions as a result of the use of a shortwave LED are just about compensated by the increased blue-green fractions of the shifted luminescent substance emission.

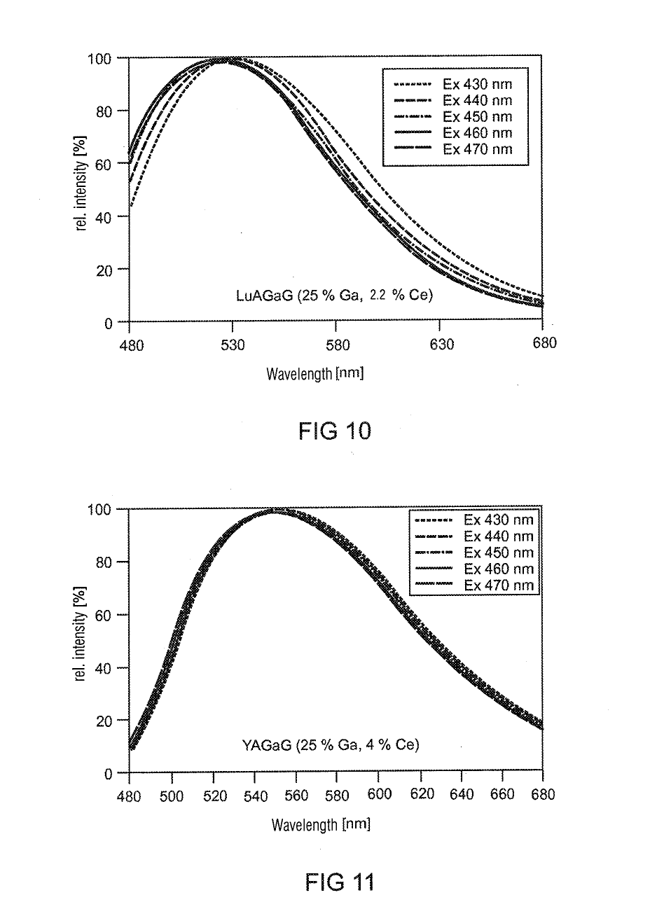

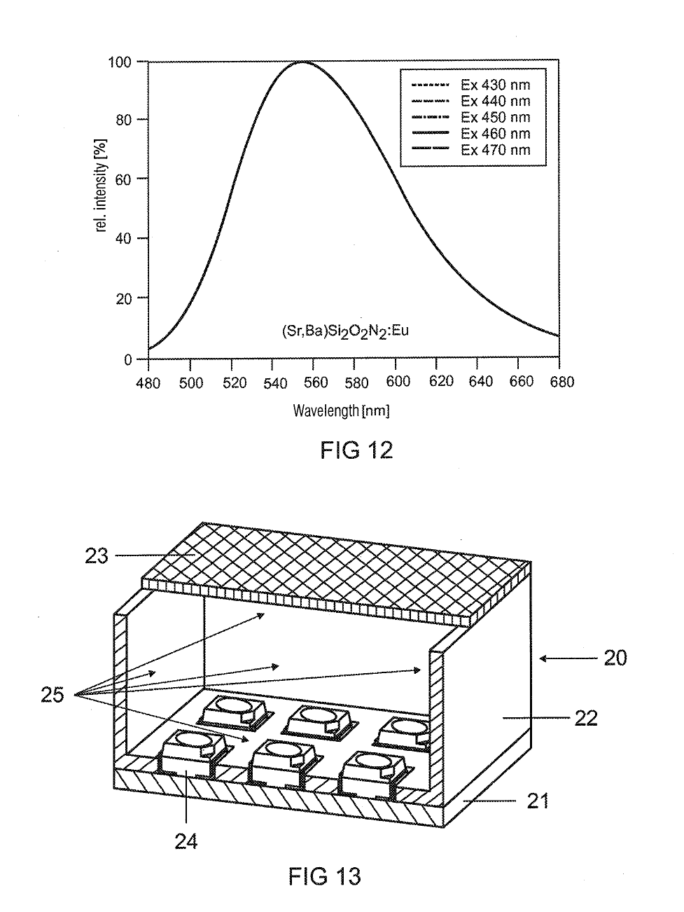

FIG. 10 shows the relative intensity in such a shift of the luminescent substance spectrum of the green-yellow luminescent substance with variable excitation wavelength between 430 and 470 nm (Ex 430 to 470) compared with YAGaG:Ce (FIG. 11) and yellow (Sr,Ba)Si2O2N2:Eu (FIG. 12).

Surprisingly the new green LuAGaG garnet behaves in a significantly different manner to the comparative luminescent substances. It has a strong green shift with a declining excitation wavelength. The comparative luminescent substances remain approximately constant. The emission spectra of the three luminescent substances are shown in comparison in the blue wavelength range between 430 and 470 nm of interest for LED applications.

The curves of FIG. 12 are practically all on top of each other so that only one curve is shown.

The use of a lutetium garnet which at most contains Y as an admixture of up to 30 mol.-%, has a significantly positive influence on color reproduction overall as a result of the altered shape of the emission spectrum. The use of Y garnets does not result in such high color reproduction values as can be obtained with Lu garnet. Details of various mixtures can be found in Tab. 2.

As an essential component, Gd is completely unsuitable and should, just like Tb or La, only be added to the component A at the most in small amounts of up to 5 mol.-% for fine tuning. In comparison, a Y fraction of up to approx. 30%, preferably with a fraction of 10 to 25%, provides a good addition to Lu. The cause is the relatively similar ionic radius of Lu and Y. However, higher values of Y would shift the emission of the luminescent substance back into a range which would interfere with the desired performance of the overall system. Compared with yttrium garnets of a similar luminescent substance emission wavelength (sample VGL 1 to VGL 4), and surprisingly even in similarly dominant luminescent substance emission wavelengths (sample VGL 3 and VGL 4), significantly higher color reproduction values Ra8 are produced in samples 1 to 3, see Table 2. As a result of this and as a result of the good excitability of short wavelengths, for the first time highly efficient shortwave blue LEDs can be used for conversion LEDs.

TABLE 2

| | Peak | | | | | |
|---|---|---|---|---|---|---|
| | wave- | | Luminescent | | | |
| | length of | Color | substance 1 | Luminescent | | |
| | the blue | tempera- | (green- | substance 2 | Ratio | |
| Sample | LED/nm | ture/K | yellow) | (orange-red) | yellow:red | Ra8 |
| VGL1 | 455 | 3150 | YAG: 2%Ce | Sr2Si5N8: Eu | 16:1 | 77 |
| VGL2 | 455 | 3200 | YAGaG: 4%Ce | Sr2Si5N8: Eu | 7:1 | 79 |
| | | | (25%Ga) | | | |
| 1 | 455 | 3200 | LuAG: 4%Ce | Sr2Si5N8: Eu | 7.8:1 | 82 |
| VGL3 | 444 | 3000 | YAGaG: 2%Ce | (Sr,Ba)2Si5N8: Eu | 10.6:1 | 85 |
| | | | (40%Ga) | (87.5% Sr) | | |
| 2 | 444 | 3050 | LuAGaG: 2.2%Ce | (Sr,Ba)2Si5N8: Eu | 12.4:1 | 89 |
| | | | (25%Ga) | (87.5% Sr) | | |
| VGL4 | 435 | 3100 | YAGaG: 2%Ce | (Sr,Ba)2Si5N8: Eu | 7:1 | 78 |
| | | | (40%Ga) | (50% Ba) | | |
| 3 | 435 | 3100 | LuAGaG: 2.2%Ce | (Sr,Ba)2Si5N8: Eu | 7:1 | 82 |
| | | | (25%Ga) | (50% Ba) | | |

In principle, the use of the luminescent substance mixture for dispersion, as a thin film, etc. directly on the LED or also as known, on a separate carrier upstream of the LED is possible. FIG. 13 shows such a module 20 with various LEDs 24 on a baseplate 21. A housing is a mounted above it with side walls 22 and a cover plate 12. The luminescent substance mixture is applied here as a layer 25 both on the side walls and above all on the cover plate 23, which is transparent.

The term luminescent substance of the type nitride silicate M2Si5N8:Eu also contains modifications of the simple nitride silicate in which Si can partially be replaced by Al and/or B and where N can be partially replaced by 0 and/or C so that through the replacement charge neutrality is ensured. Such modified nitride silicates are known per se, see for example EP-A 2 058 382. Formally such a nitride silicate can be described as M2X5Y8:D, with M=(Ba,Sr) and X=(Si,A,B) and Y=(N,O,C) and D=Eu alone or with co-doping.

Tab. 3 shows various garnets from the A3B5O12:Ce system with A selected from (Lu,Y). It is demonstrated that for A=Lu through to A=70% Lu, remainder Y good values can be obtained. At the same time the ratio between Al and Ga must be carefully selected for component B. The Ga fraction should be between 10 and 40 mol.-%, in particular 10 to 25%. Table 7 shows various A3B5O12:Ce (Lu, Y) garnets, where the concentration of the activator Ce is 2% respectively of A and A=Lu, Y (the fraction of Lu is specified, remainder is Y) and B=Al, Ga (the fraction Ga is specified, remainder is Al). Pure LuAG:Ce or YAG:Ce is unsuitable. Likewise, the addition of Pr is extremely detrimental to the efficiency of the luminescent substance and should be avoided if possible.

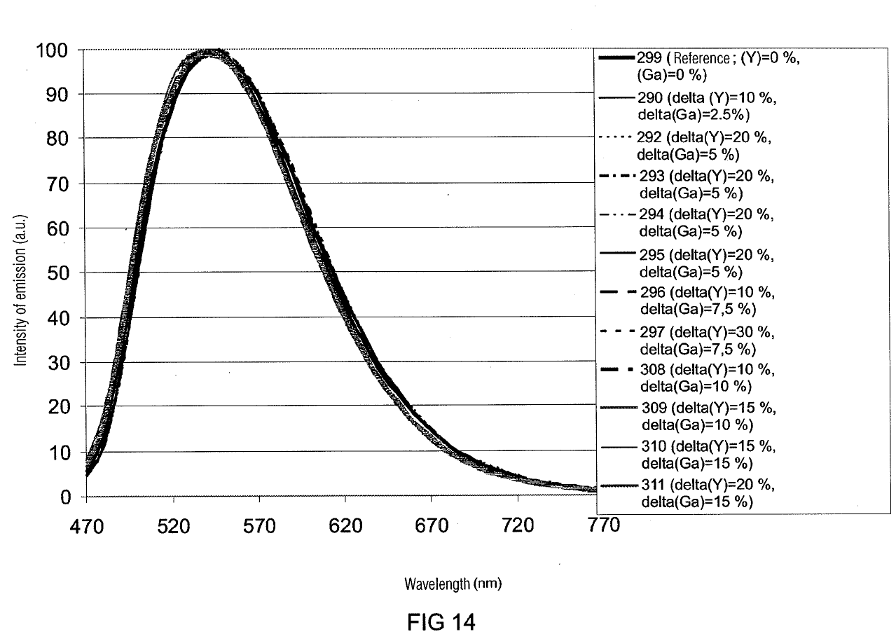

FIG. 14 shows the emission spectra for various garnets in which the fraction of Y was varied. It is demonstrated that the emission for small fraction Y remains almost constant.

Tab. 4 shows pure LuAGAG luminescent substances with gradually increased Ga fraction. These table values, including those of the other tables, always relate in principle to a pure reference excitation at 460 nm.

TABLE 4
A3B5O12: Ce Lu(A1, Ga garnets (so-called LuAGAG)

| | Fraction Lu, | Fraction Ga, | | | lambda | | rel. |
|---|---|---|---|---|---|---|---|
| Sample number | remainder Y | remainder Al | X | y | dom/ni | FWHM/ni | QE |
| SL 315c/08 | 100% | 5.0% | 0.350 | 0.567 | 557.5 | 109.1 | 1.00 |
| SL 005c/09 | 100% | 15.0% | 0.337 | 0.572 | 555.1 | 104.3 | 1.01 |
| SL 003c/09 | 100% | 20.0% | 0.351 | 0.564 | 557.7 | 108.4 | 1.05 |
| SL 167c/08 | 100% | 25.0% | 0.352 | 0.562 | 557.9 | 109.8 | 1.05 |

TABLE 3
A3B5O12: Ce (Lu, Y) garnets

| | Fraction Lu, | Fraction Ga, | | | lambda | | rel. |
|---|---|---|---|---|---|---|---|
| Sample number | remainder Y | remaindert AI | X | y | dom/nm | FWHM/nm | QE |
| SL 299c/08 | 100% | 0.0% | 0.393 | 0,557 | 564.2 | 112.5 | 1.00 |
| SL 290c/08 | 88% | 2.5% | 0.396 | 0.556 | 564.6 | 113.2 | 1.02 |
| SL291c/08 | 68% | 2.5% | 0.414 | 0.550 | 567.1 | 115.4 | 1.01 |
| SL 292c/08 | 78% | 5.0% | 0.400 | 0.555 | 565.2 | 113.7 | 1.01 |
| SL 293c/08 | 78% | 5.0% | 0.400 | 0.556 | 565.1 | 114.3 | 1.01 |
| SL 294c/08 | 78% | 5.0% | 0.401 | 0.555 | 565.3 | 114.8 | 1.02 |
| SL 295c/08 | 78% | 5.0% | 0.401 | 0.555 | 565.3 | 113.8 | 1.02 |
| SL 296c/08 | 88% | 7.5% | 0.388 | 0.559 | 563.5 | 112.8 | 1.02 |
| SL 297c/08 | 68% | 7.5% | 0.402 | 0.555 | 565.4 | 114.4 | 1.03 |
| SL 308c/08 | 88% | 10.0% | 0.383 | 0.560 | 562.8 | 112.1 | 1.03 |
| SL 309c/08 | 83% | 10.0% | 0.387 | 0.559 | 563.3 | 112.5 | 1.03 |
| SL310c/08 | 83% | 15.0% | 0.381 | 0.560 | 562.5 | 113.0 | 1.03 |
| SL311c/08 | 78% | 15.0% | 0.385 | 0.559 | 563.1 | 112.3 | 1.02 |

1. A conversion LED with a chip which emits primary blue radiation, and a layer containing luminescent substance upstream of the chip which converts at least part of the primary radiation of the chip into secondary radiation, wherein a first garnet A3B5O12:Ce yellow-green emitting luminescent substance and a second nitride silicate M2X5Y8:D orange-red emitting luminescent substance is used, wherein the peak wavelength of the primary radiation is in the range of 430 to 450 nm, while the first luminescent substance is a garnet with the cation A=Lu or a mixture of Lu, Y with up a Y fraction of up to 30%, and wherein B has fractions of both Al and Ga, while the second luminescent substance is a nitride silicate which contains both Ba and Sr as cation M, and in which the doping consists of Eu, wherein the second luminescent substance contains 35 to 75 mol.-% Ba for the component M, remainder is Sr, where X=Si and Y=N.

2. The conversion LED as claimed in claim 1, wherein in component B the first luminescent substance contains 10% to 40 mol.-% Ga, remainder is Al.

3. The conversion LED as claimed in claim 1, wherein the first luminescent substance contains 1.5% to 2.9 mol.-% Ce, in the component A, remainder is A.

4. The conversion LED as claimed in claim 1, wherein the second luminescent substance contains 35 to 65 mol.-% Ba in the component M, remainder is Sr, where X=Si and Y=N.

5. The conversion LED as claimed in claim 1, wherein the second luminescent substance contains 1 to 20 mol.-% Eu in the component M, remainder is (Ba, Sr).

6. The conversion LED as claimed in claim 1, wherein the second luminescent substance is (Sr0.48Ba0.48Eu0.04)2Si5N8.

7. The conversion LED as claimed in claim 6, wherein the first luminescent substance is A3B5O12, with A=75 to 100% Lu, remainder Y and a Ce content of 1.5 to 2.5%, with B=10 to 40% Ga, remainder Al.

8. The conversion LED as claimed in claim 7, wherein the first luminescent substance is A3B5O12, with A=80 to 100% Lu, remainder Y and a Ce content of 1 to 2.5%, with B=15 to 30% Ga, remainder Al.

9. The conversion LED as claimed in claim 8, wherein the first luminescent substance is (Lu0.978Ce0.022)3A13.75Gal.25012.

10. The conversion as claimed in claim 1, wherein the peak wavelength of the primary radiations is up to 445 nm.

11. The conversion LED as claimed in claim 1, wherein in component B the first luminescent substance contains 20% to 30 mol.-% Ga, remainder is Al.

12. The conversion LED as claimed in claim 1, wherein the first luminescent substance contains 1.8 to 2.6 mol.-% Ce in the component A, remainder is only Lu or Lu with a Y fraction of up to 25%.

13. The conversion LED as claimed in claim 1, wherein the second luminescent substance contains 40 to 60 mol.-% Ba in the component M, remainder is Sr, where X=Si and Y=N.

14. The conversion LED as claimed in claim 1, wherein the second luminescent substance contains 2 to 6% mol.-% Eu in the component M, remainder is (Ba, Sr).
